(19) United States
(12) Patent Application Publication
(10) Pub. No.: US 2025/0105069 A1
(43) Pub. Date: Mar. 27, 2025

(54) SEMICONDUCTOR DEVICE

(71) Applicant: FUJI ELECTRIC CO., LTD., Kawasaki-shi (JP)

(72) Inventors: Eri KAMEDA, Kawasaki-shi (JP); Tsubasa NAKAMURA, Kawasaki-shi (JP); Kengo INOUE, Kawasaki-shi (JP)

(73) Assignee: FUJI ELECTRIC CO., LTD., Kawasaki-shi (JP)

(21) Appl. No.: 18/790,813

(22) Filed: Jul. 31, 2024

(30) Foreign Application Priority Data
Sep. 21, 2023 (JP) 2023-155814

(51) Int. Cl. H01L 23/047; H01L 23/373; H01L 25/07

(52) U.S. Cl. CPC H01L 23/047; H01L 23/3735; H01L 25/072

(57) ABSTRACT

A semiconductor device includes a circuit substrate having a semiconductor element thereon, a case surrounding a periphery of the circuit substrate so as to house the circuit substrate therein, and a lid disposed above the circuit substrate so as to close the case at an upper side thereof. The lid includes a plurality of extending portions including a first extending portion and a second extending portion, and a plurality of deformation holes respectively provided for one of the plurality of extending portions. The plurality of extending portions each extend from a lower surface of the lid facing the circuit substrate toward the circuit substrate and have a protrusion at an end thereof. The protrusion of the first extending portion protrudes in a first direction and the protrusion of the second extending portion protrudes in a second direction opposite to the first direction. The case includes a plurality of hooked portions that respectively hook on respective ones of the protrusions of the plurality of extending portions.

### CROSS-REFERENCE TO RELATED APPLICATION

This application is based upon and claims the benefit of priority to Japanese Patent Application No. 2023-155814, filed on Sep. 21, 2023, the entire contents of which are incorporated herein by reference.

### BACKGROUND OF THE INVENTION

### 1. Technical Field

The present invention relates to a semiconductor device in which a lid is fitted into a case.

### 2. Description of the Related Art

In the related art, a semiconductor device includes a circuit substrate on which a semiconductor element such as an insulated gate bipolar transistor (IGBT) is mounted, and is used for an inverter device or the like (see, for example, JP 3237816 U, WO 2017/163638 A, JP 2023-88146 A, JP 2022-65692 A, WO 2019/058454 A, JP 2021-72329 A, JP 2021-129451 A, JP 2018-139278 A, JP 2021-114511 A, and JP 2014-150204 A).

### SUMMARY OF THE INVENTION

However, when a lid is disposed in a semiconductor device, it can be said that fitting is an easy and simple configuration, but from the viewpoint of protecting a circuit substrate and the like, it is required to reliably fit the lid into a case. Therefore, it is conceivable to provide a protrusion for fitting in an extending portion extending downward from the lid. However, in this case, the extending portion extends downward long in order to alleviate the reaction force due to the deformation when the protrusion is hooked on the case, and the height of the semiconductor device increases.

An object of the present invention is to provide a semiconductor device capable of reliably fitting a lid into a case and achieving height reduction.

According to an aspect, a semiconductor device includes a case that houses a circuit substrate on which a semiconductor element is mounted in a substrate housing region; and a lid that covers the substrate housing region, in which the lid includes a plurality of extending portions including a first extending portion extending toward the substrate housing region side and including a protrusion protruding in a first direction and a second extending portion extending toward the substrate housing region side and including a protrusion protruding in a second direction opposite to the first direction, and a plurality of deformation holes, and the case includes a plurality of hook portions on which the protrusions of the extending portions are respectively hooked.

According to the above aspect, the lid can be reliably fitted into the case, and the height reduction can be achieved.

### BRIEF DESCRIPTION OF THE DRAWINGS

FIG. 1 is a plan view illustrating a semiconductor device according to an embodiment;

FIG. 2 is a perspective view illustrating the semiconductor device according to the embodiment;

FIG. 3 is a plan view illustrating the semiconductor device in a state where a lid is removed according to the embodiment;

FIG. 4 is a perspective view illustrating the semiconductor device in a state where the lid is removed according to the embodiment;

FIG. 5 is a cross-sectional view taken along line V-V of FIG. 1;

FIG. 6 is an enlarged view of a VI portion in FIG. 1;

FIG. 7 is a cross-sectional view taken along line VII-VII of FIG. 6;

FIG. 8 is an enlarged view of a VIII portion in FIG. 1;

FIG. 9 is a cross-sectional view taken along line IX-IX of FIG. 8;

FIG. 10 is a plan view (corresponding to FIG. 6 which is an enlarged view of the VI portion in FIG. 1) illustrating a second deformation hole and the like in a first modification of the embodiment; and

FIG. 11 is a cross-sectional view (corresponding to FIG. 9 that is the cross-sectional view taken along line IX-IX of FIG. 8) illustrating a fourth deformation hole and the like in a second modification of the embodiment.

### DETAILED DESCRIPTION

Hereinafter, a semiconductor device according to an embodiment of the present invention is described with reference to the drawings. Note that the present invention is not limited to the embodiment described below, and thus appropriate modifications can be made without departing from the gist thereof.

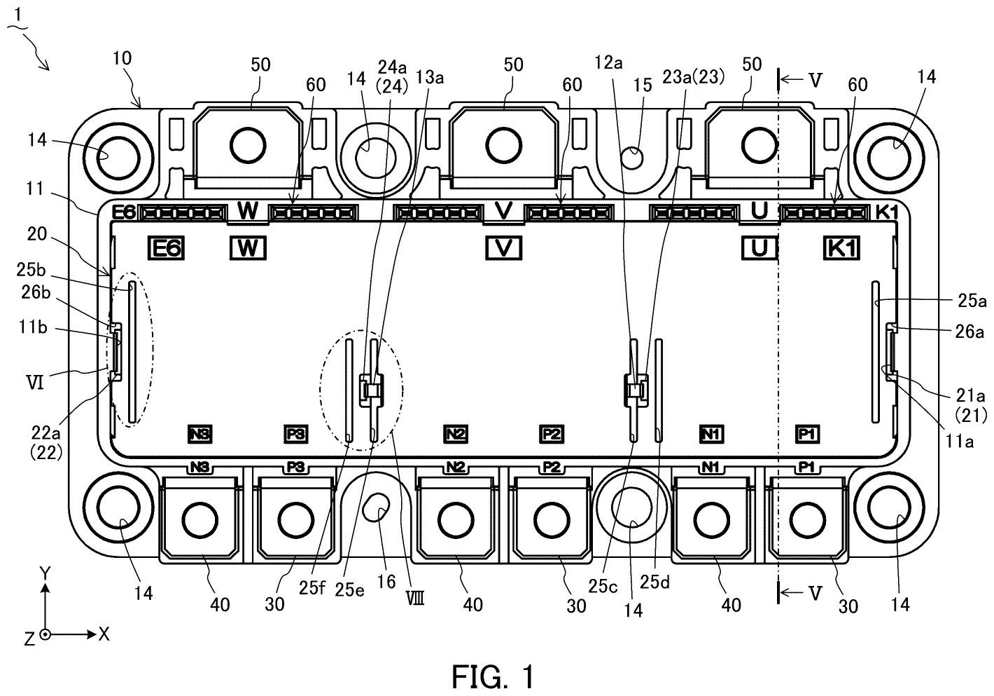

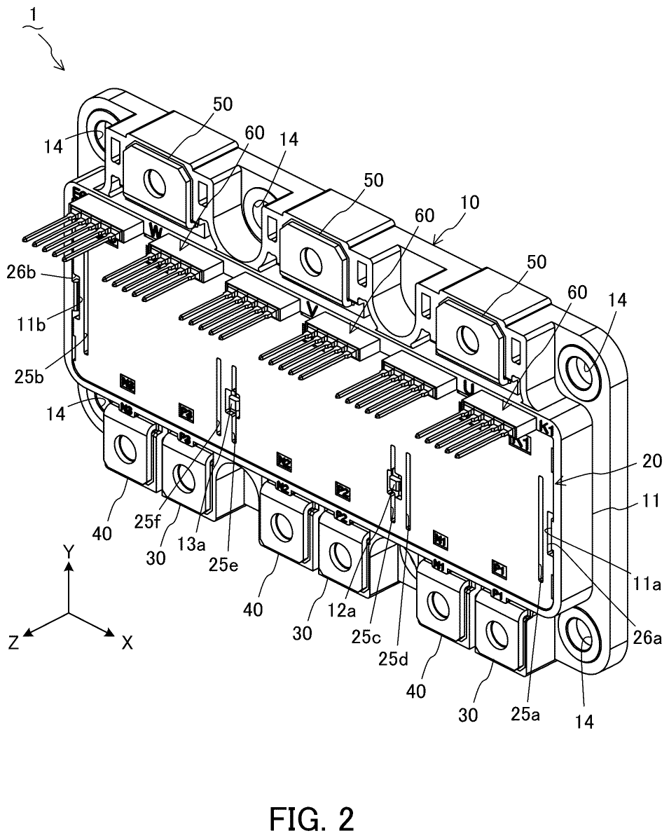

FIGS. 1 and 2 are a plan view and a perspective view illustrating a semiconductor device 1 according to the embodiment.

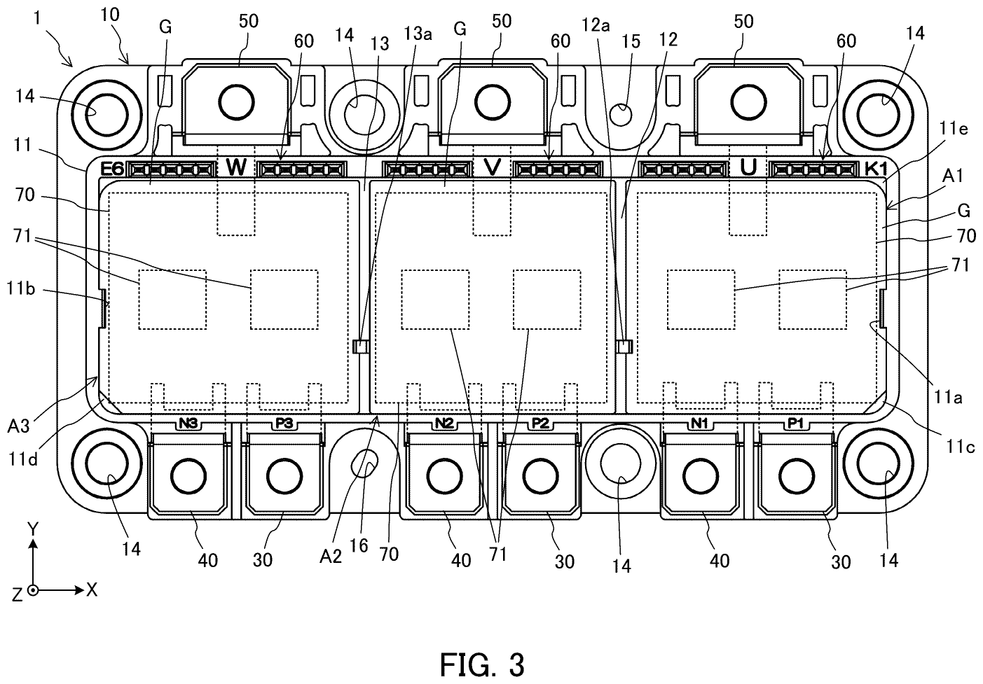

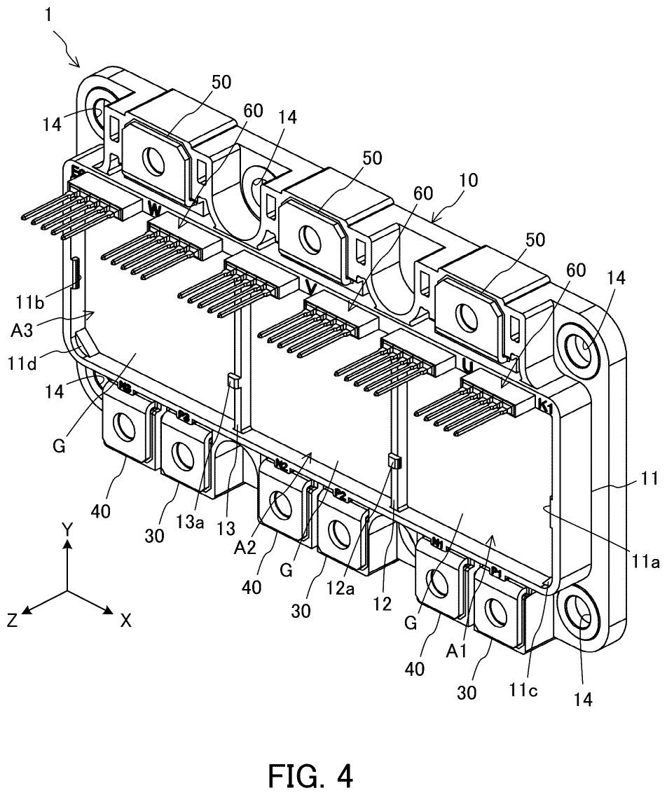

FIGS. 3 and 4 are a plan view and a perspective view illustrating the semiconductor device 1 in in a state where a lid 20 is removed.

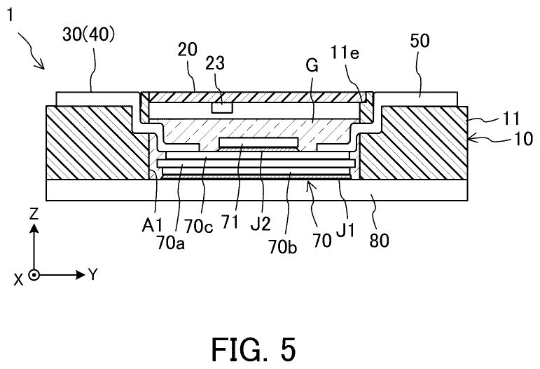

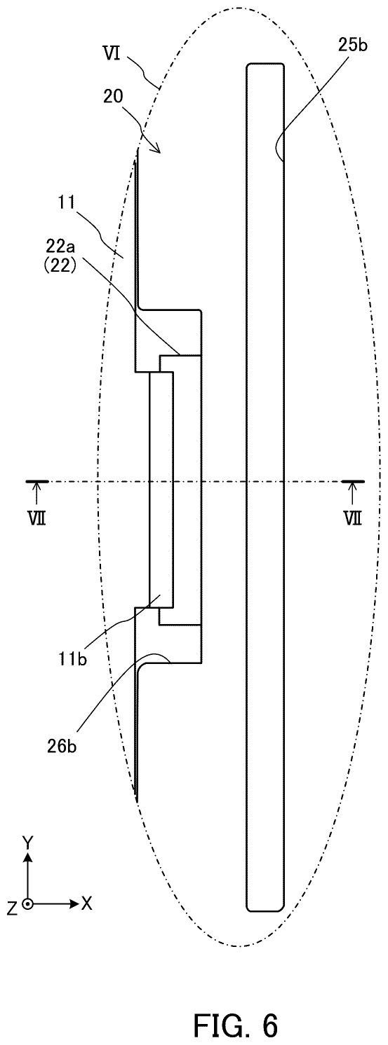

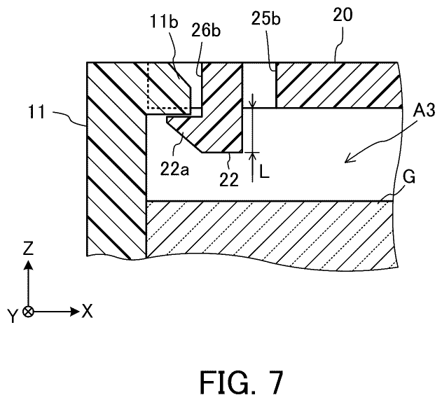

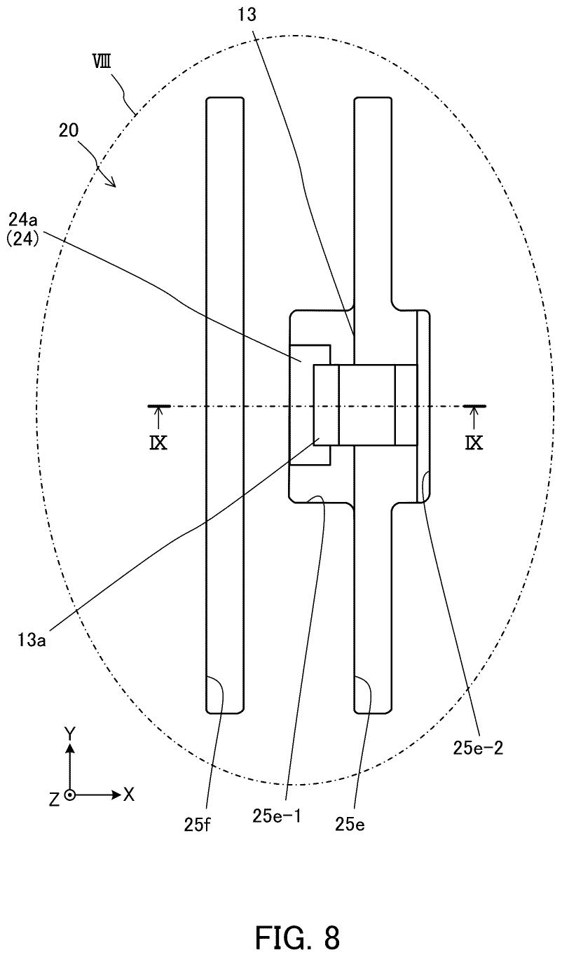

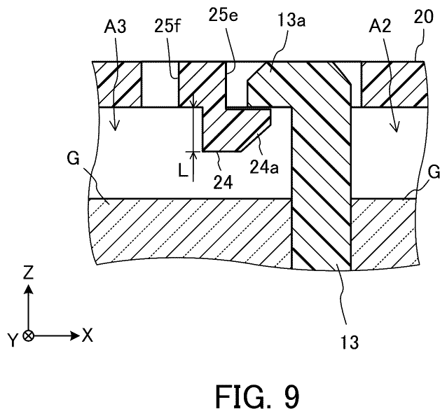

FIG. 5 is a cross-sectional view taken along line V-V of FIG. 1. FIG. 6 is an enlarged view of a VI portion in FIG. 1. FIG. 7 is a cross-sectional view taken along line VII-VII of FIG. 6. FIG. 8 is an enlarged view of a VIII portion in FIG. 1. FIG. 9 is a cross-sectional view taken along line IX-IX of FIG. 8.

Note that, with respect to X, Y, and Z directions indicated in FIGS. 1 to 9 and FIGS. 10 and 11 described below, the vertical direction of the semiconductor device 1 (thickness direction of a circuit substrate 70) is defined as the Z direction. From among the X and Y directions orthogonal to the Z direction, the longitudinal direction of the semiconductor device 1 (the lid 20) is defined as the X direction, and the short direction of the semiconductor device 1 (the lid 20) is defined as the Y direction. In some cases, the X direction may be referred to as a left-right direction, the Y direction may be referred to as a front-back direction, and the Z direction may be referred to as a vertical direction. Such directional terms are used for convenience of description. Thus, depending on the installation posture of the semiconductor device 1, the correspondence relationship with the X, Y, and Z directions varies.

The semiconductor device 1 according to the present embodiment is applied, for example, to a power converter, such as a power control unit, and serves as a power semiconductor module configuring an inverter circuit. The application of the semiconductor device 1 is arbitrary, but the semiconductor device 1 is used, for example, as an inverter device for an in-vehicle or industrial motor.

As illustrated in FIGS. 3 and 5, the semiconductor device 1 includes a case 10 that houses three circuit substrates 70 (in FIG. 3, the circuit substrates are positioned inside gel G and thus are illustrated by broken lines which are hidden lines) on which semiconductor elements 71 are mounted in substrate housing regions A1, A2, and A3, and the lid 20 that covers the substrate housing regions A1, A2, and A3. Note that, in FIG. 5, hatching representing a cross section is applied to the case 10, the lid 20, and the gel G.

As illustrated in FIGS. 3 and 4, the case 10 has a rectangular shape in plan view, and a cylindrical housing wall 11 protrudes upward from the upper surface. Inside the housing wall 11, three substrate housing regions A1 to A3 each housing the circuit substrate 70 are positioned. These substrate housing regions A1 to A3 have the same or substantially the same size in plan view.

A first hook portion 11a that protrudes toward the substrate housing region A1 side (the negative side in the X direction) is provided from the right end of the housing wall 11. In addition, a second hook portion 11b protruding toward the substrate housing region A3 side (the positive side in the X direction) is provided from the left end of the housing wall 11. The first hook portion 11a and the second hook portion 11b are provided on the upper portion of the inner peripheral surface of the housing wall 11. Protrusions 21a and 22a of a first extending portion 21 and a second extending portion 22 of the lid 20 illustrated in FIGS. 1 and 2 described below are hooked on the first hook portion 11a and the second hook portion 11b. Note that, in FIGS. 3 and 4, the first hook portion 11a and the second hook portion 11b are provided in the center of the housing wall 11 in the short direction of the case 10, but the position in the short direction is not particularly limited.

As illustrated in FIGS. 3 and 4, lid receivers 11c and 11d on which the lid 20 is placed are provided at a right front corner and a left front corner in the housing wall 11. As illustrated in FIG. 3, a lid receiver 11e having the same height as a first partition wall 12 and a second partition wall 13 is provided in the rear portion in the housing wall 11 across the right rear corner and the left rear corner.

The case 10 includes the first partition wall 12 and the second partition wall 13 that partition the three substrate housing regions A1 to A3 arranged in the X direction. Note that a metal base 80 described below is disposed below each of the substrate housing regions A1 to A3, and the case 10 penetrates each of the substrate housing regions A1 to A3 in the vertical direction and is hollow.

A third hook portion 12a protruding toward the substrate housing region A1 side (the positive side in the X direction) is provided on the upper surface of the first partition wall 12. A fourth hook portion 13a protruding toward the substrate housing region A3 side (the negative side in the X direction) is provided on the upper surface of the second partition wall 13. The upper surface of the third hook portion 12a is positioned above the upper surface of the other portion of the first partition wall 12. Also, the upper surface of the fourth hook portion 13a is positioned above the upper surface of the other portion of the second partition wall 13. Protrusions 23a and 24a of a third extending portion 23 and a fourth extending portion 24 of the lid 20 are hooked on the third hook portion 12a and the fourth hook portion 13a. The third hook portion 12a and the fourth hook portion 13a are examples of an intermediate hook portion. The case 10 is fitted into the lid 20 by a snap-fit structure configured with the hook portions 11a, 11b, 12a, and 13a and the protrusions 21a to 24a described above. The hook portions 11a, 11b, 12a, and 13a are integrally provided with the case 10, for example, by injection molding. Note that the protrusions 21a to 24a and the extending portions 21 to 24 can also be referred to as claws. In addition, the hook portions 11a, 11b, 12a, and 13a may be recesses (recess portions) provided in a wall surface or the like of the case 10 (the housing wall 11, the first partition wall 12, or the second partition wall 13). Further, regions below the hook portions 11a, 11b, 12a, and 13a can be regarded as recess portions.

In the case 10, a plurality of (for example, six as illustrated in FIG. 3) fixing holes 14 are formed along the outer peripheral edge. For example, the fixing hole 14 serve as a hole for inserting a bolt for fixing the semiconductor device 1 and an external device such as a cooler (not illustrated) together.

The case 10 has a positioning hole 15 provided on the positive side in the Y direction with respect to the housing wall 11 and a positioning hole 16 provided on the negative side in the Y direction with respect to the housing wall 11. The positions of the positioning holes 15 and 16 in the X direction are different from each other. While the positioning hole 15 has a circular shape in plan view, the positioning hole 16 is a long hole extending obliquely toward the positioning hole 15 in plan view. As a result, for example, even if the interval between a positioning pin of the external device inserted into the positioning hole 15 and a positioning pin of the external device to be inserted into the positioning hole 16 varies due to tolerance or the like, the two positioning pins can be inserted into the positioning holes 15 and 16.

Note that, for example, a resin for the case 10 can be selected from insulating resins such as polyphenylene sulfide (PPS), polybutylene terephthalate (PBT), polybutyl acrylate (PBA), polyamide (PA), acrylonitrile butadiene styrene (ABS), a liquid crystal polymer (LCP), polyether ether ketone (PEEK), polybutylene succinate (PBS), urethane, and silicone. In addition, the resin to be selected may be a mixture of two or more types of resins. A filler (for example, a glass filler) for improvement in strength or functionality may be included in the resin.

As illustrated in FIGS. 4 and 5, the gel G injected into the substrate housing regions A1 to A3 seals the circuit substrate 70, the semiconductor element 71 mounted on the circuit substrate 70, and the like. The gel G is, for example, transparent silicone gel. A sealing resin may be used instead of the gel G. The sealing resin is configured, for example, with a thermosetting resin. The sealing resin preferably includes any one of epoxy, silicone, urethane, polyimide, polyamide, and polyamide-imide. As the sealing resin, for example, an epoxy resin to which a filler is mixed is preferable in view of insulation properties, heat resistance, and heat dissipation.

As illustrated in FIG. 1 and FIGS. 6 to 9, the lid 20 includes the first extending portion 21, the second extending portion 22, the third extending portion 23, and the fourth extending portion 24 each extending to the negative side in the Z direction. These extending portions 21 to 24 are integrally provided with the lid 20, for example, by injection molding. The first extending portion 21 and the fourth extending portion 24 include the protrusions 21a and 24a protruding to the positive side in the X direction which is an example of the first direction. The second extending portion 22 and the third extending portion 23 include the protrusions 22a and 23a protruding to the negative side in the X direction which is an example of the second direction opposite to the first direction.

The first extending portion 21 is positioned on one end (right end) side of the lid 20 in the longitudinal direction (X direction), and the second extending portion 22 is positioned on the other end (left end) side of the lid 20 in the longitudinal direction. That is, the first extending portion 21 and the second extending portion 22 are positioned on both end sides of the lid 20 in the longitudinal direction, and the protrusions 21a and 22a protrude to be away from each other in the longitudinal direction of the lid 20. When the lid 20 has a square shape in plan view, both the left-right direction (X direction) and the front-back direction (Y direction) can be referred to as the longitudinal direction of the lid 20.

As illustrated in FIGS. 6 and 7, the second extending portion 22 extends to the negative side in the Z direction from a position adjacent to a recess portion 26b provided at an end portion (left end) of the lid 20 in the longitudinal direction (X direction) (length L as a height). That is, the second extending portion 22 is provided at a position recessed from the left end of the lid 20 in the longitudinal direction (X direction) to the right side (the positive side in the X direction).

The first extending portion 21 is bilaterally symmetrical with the second extending portion 22 and extends toward the negative side in the Z direction from a position adjacent to a recess portion 26a provided at an end portion (right end) of the lid 20 in the longitudinal direction (X direction) as illustrated in FIGS. 1 and 2, similarly to the second extending portion 22. That is, the first extending portion 21 is provided at a position recessed from the right end of the lid 20 in the longitudinal direction (X direction) to the left side (the negative side in the X direction).

As illustrated in FIGS. 1 and 2, the third extending portion 23 is positioned closer to the first extending portion 21 side (the positive side in the X direction) than the center of the lid 20 in the longitudinal direction so that the protrusion 23a is hooked on the third hook portion 12a of the first partition wall 12. The fourth extending portion 24 is positioned on the second extending portion 22 side (the negative side in the X direction) with respect to the center of the lid 20 in the longitudinal direction so that the protrusion 24a is hooked on the fourth hook portion 13a of the second partition wall 13. The third extending portion 23 and the fourth extending portion 24 are examples of one or more intermediate extending portions, the position thereof in the longitudinal direction (X direction) of the lid 20 is positioned between the first extending portion 21 and the second extending portion 22. As the intermediate extending portion, only one of the third extending portion 23 and the fourth extending portion 24 may be provided, or an extending portion having a protrusion protruding in a direction different from the protrusions 23a and 24a of the third extending portion 23 and the fourth extending portion 24 may be provided. In these cases, the intermediate hook portions exemplifying the third hook portion 12a and the fourth hook portion 13a and an intermediate deformation holes described below may be provided in the number and orientation corresponding to the intermediate extending portion.

As illustrated in FIGS. 8 and 9, the fourth extending portion 24 extends from between fourth deformation holes 25e and 25f provided in the lid 20 to the negative side in the Z direction (length (height) L). The third extending portion 23 is bilaterally symmetrical with the fourth extending portion 24 and extends toward the negative side in the Z direction from between third deformation holes 25c and 25d provided in the lid 20.

As illustrated in FIGS. 1 and 2, the lid 20 includes a first deformation hole 25a, a second deformation hole 25b, the third deformation holes 25c and 25d, and the fourth deformation holes 25e and 25f as example of a plurality of deformation holes for alleviating (releasing) reaction force due to deformation of the first extending portion 21, the second extending portion 22, the third extending portion 23, and the fourth extending portion 24. The first deformation hole 25a alleviates reaction force due to deformation of the first extending portion 21, the second deformation hole 25b alleviates reaction force due to deformation of the second extending portion 22, the third deformation holes 25c and 25d alleviate reaction force due to deformation of the third extending portion 23, and the fourth deformation holes 25e and 25f alleviate reaction force due to deformation of the fourth extending portion 24. The center positions of the deformation holes 25a to 25f in the Y direction respectively coincide with the center positions of the extending portions 21 to 24 of which the reaction force due to the deformation is to be alleviated. The deformation holes 25a to 25f extend respectively longer than the extending portions 21 to 24 of which the reaction force due to the deformation is to be alleviated in the direction (Y direction) orthogonal to the longitudinal direction (X direction) of the lid 20 and the depth direction (Z direction) of the substrate housing regions A1 to A3 in a straight line shape. That is, the deformation holes 25a to 25f extend longer in the front and back direction in the Y direction respectively than the extending portions 21 to 24 of which the reaction force due to the deformation is to be alleviated. However, at least one of the deformation holes 25a to 25f may extend in a direction different from the Y direction or a curved shape or may be formed in another shape such as a circular shape or an elliptical shape. The deformation holes 25a to 25f penetrate the lid 20 in the thickness direction (Z direction). The third deformation holes 25c and 25d are examples of intermediate deformation holes that alleviate reaction force due to deformation of the third extending portion 23 on both sides of the third extending portion 23 (intermediate extending portion) in the longitudinal direction (X direction) of the lid 20. Similarly, the fourth deformation holes 25e and 25f are examples of intermediate deformation holes that alleviate reaction force due to deformation of the fourth extending portion 24 on both sides of the fourth extending portion 24 (intermediate extending portion) in the longitudinal direction (X direction) of the lid 20. Here, if the deformation holes 25a to 25f are positioned around the extending portion 21 to 24, for example, by narrowing down the width of the extending portions 21 to 24 in an arbitrary direction to promote the deformation of the extending portions 21 to 24 or by absorbing the deformation of the extending portions 21 to 24 by the deformation holes 25a to 25f, it can be said that the reaction force due to the deformation of the extending portion 21 to 24 can be alleviated (released).

The first deformation hole 25a and the second deformation hole 25b are provided adjacent to the first extending portion 21 and the second extending portion 22 (see the second extending portion 22 and the second deformation hole 25b in FIG. 7). The first deformation hole 25a is bilaterally symmetrical with the second deformation hole 25b.

As illustrated in FIG. 8, among the fourth deformation holes 25e and 25f, the fourth deformation hole 25e positioned on the positive side in the X direction with respect to the fourth extending portion 24 includes a recess portion 25e-1 recessed in a direction opposite to the positive side in the X direction in which the protrusion 24a of the fourth extending portion 24 protrudes. The recess portion 25e-1 is positioned so as to sandwich the fourth extending portion 24 with the fourth deformation hole 25f in plan view and thus is positioned in the same region as the protrusion 24a. Also, the fourth deformation hole 25e has a recess portion 25e-2 recessed on the positive side in the X direction opposite to the recess portion 25e-1. It can be said that these recess portions 25e-1 and 25e-2 are provided to avoid interference with the fourth hook portion 13a of the second partition wall 13. It can also be said that the one recess portion 25e-1 is provided to shorten the width of the fourth extending portion 24 in the X direction.

The third deformation holes 25c and 25d are bilaterally symmetrical with the fourth deformation holes 25e and 25f, and the third deformation hole 25c positioned on the negative side in the X direction with respect to the third extending portion 23 among the third deformation holes 25c and 25d includes a recess portion (bilaterally symmetrical with the recess portion 25e-1) recessed in a direction opposite to the negative side in the X direction in which the protrusion 23a of the third extending portion 23 protrudes. The recess portion is positioned so as to sandwich the third extending portion 23 with the third deformation hole 25d in plan view and thus is positioned in the same region as the protrusion 23a. The third deformation hole 25c includes a recess portion (bilaterally symmetrical with the recess portion 25e-2) recessed to the negative side in the X direction opposite to the recess portion described above. It can be said that these recess portions are provided to avoid interference with the third hook portion 12a of the first partition wall 12. It can also be said that the one recess portion (bilaterally symmetrical with the recess portion 25e-1) is provided to shorten the width of the third extending portion 23 in the X direction.

As illustrated in FIGS. 1 and 2, characters such as “U”, “V”, “W”, “P1”, “N1”, “P2”, “N2”, “P3”, “N3”, “K1”, and “E6” are formed on the upper surface of the lid 20 so as to protrude upward in a rectangular region recessed downward. The upper surface of each character coincides with the upper surface of the lid 20 or is positioned below the upper surface of the lid 20.

As illustrated in FIGS. 1 to 4, the case 10 is provided with main terminals (P terminals 30, N terminals 40, and M terminals 50) functioning as an external connecting terminal for connection to an external conductor and a control terminal 60. One P terminal 30, one N terminal 40, and one M terminal 50 are arranged for each circuit substrate 70. The P terminal 30 may be each referred to as a positive terminal (input terminal) or a first main terminal. The N terminal 40 may be each referred to as a negative terminal (output terminal) or a second main terminal. The M terminal 50 may be each referred to as an intermediate terminal (output terminal) or a third main terminal.

The P terminal 30 and the N terminal 40 are positioned on the negative side in the Y direction with respect to the circuit substrate 70. Also, the M terminal 50 is positioned on the positive side in the Y direction with respect to the circuit substrate 70. For example, the P terminal 30, the N terminal 40, and the M terminal 50 may be formed to be bent by press processing or the like using a metal material such as a copper material, a copper-alloy-based material, an aluminum-alloy-based material, or an iron-alloy-based material.

The P terminal 30, the N terminal 40, and the M terminal 50 are fastened to the external conductor by screws on one end side and are bonded and electrically connected to the circuit substrate 70 (for example, a circuit board 70c of the circuit substrate 70 or a copper block (not illustrated) provided on the circuit board 70c) on the other end side, for example, while being bent a plurality of times as illustrated in FIG. 5.

The three circuit substrates 70 on which the semiconductor elements 71 are mounted respectively correspond, for example, to a U phase, a V phase, and a W phase and form a three-phase inverter circuit as a whole. Each of the three circuit substrates 70 on which the semiconductor element 71 is mounted may be referred to as a power cell or a semiconductor unit.

The circuit substrate 70 is configured with, for example, a direct copper bonding (DCB) substrate, an active metal brazing (AMB) substrate, or a metal base substrate. As illustrated in FIG. 5, the circuit substrate 70 includes an insulating plate 70a, a heat dissipation plate 70b disposed on the lower surface of the insulating plate 70a, and the plurality of circuit boards 70c disposed on the upper surface of the insulating plate 70a. The circuit substrate 70 can be referred to as a laminated substrate and is formed, for example, in a rectangular shape in plan view.

For example, the insulating plate 70a is formed of an insulating material such as a ceramic material such as aluminum oxide (Al₂O₃), aluminum nitride (AlN), silicon nitride (Si₃N₄), or a composite material of aluminum oxide and zirconium oxide (ZrO₂), a resin material such as epoxy, or an epoxy resin material using a ceramic material as a filler. The insulating plate 70a may be referred to as an insulating layer or an insulating film.

The heat dissipation plate 70b has a predetermined thickness in the Z direction and is formed on the lower surface of the insulating plate 70a. For example, the heat dissipation plate 70b is formed of a metal plate having good thermal conductivity such as copper and aluminum. The heat dissipation plate 70b is bonded to an upper surface of the metal base 80 by a bonding material J1 such as solder.

The number of circuit boards 70c formed on the upper surface of the insulating plate 70a may be any number of one or more. The circuit boards 70c are metal layers such as copper foil and the plurality of circuit boards 70c are formed in an island shape in a mutually electrically insulated state on the insulating plate 70a. Note that the circuit board 70c may be each referred to as a circuit layer.

The semiconductor element 71 is mounted on a mounting surface, which is an upper surface of the circuit substrate 70 (circuit board 70c), via a bonding material J2. In FIG. 3, two semiconductor elements 71 are illustrated for each circuit substrate 70, but the number of semiconductor elements 71 is arbitrary. For example, the semiconductor element 71 is formed in a square or rectangular shape in plan view with a semiconductor substrate based on silicon (Si), silicon carbide (SiC), gallium nitride (GaN), or diamond.

Note that a switching element such as an IGBT or a power metal oxide semiconductor field effect transistor (MOSFET), or a diode such as a free wheeling diode (FWD) may be used as the semiconductor element 71. Such a switching element and a diode may be made in antiparallel connection. As the semiconductor element 71, used may be a reverse conducting (RC)-IGBT element of an IGBT and an FWD in unification, a power MOSFET element, or a reverse blocking (RB)-IGBT element highly resistant to a reverse bias. In particular, in the RC-IGBT element, bidirectional energization can achieve the miniaturization of the internal circuit and in turn the miniaturization of the semiconductor device 1 (circuit substrate 70).

The semiconductor elements 71 are each made in electrically conductive connection with the predetermined circuit board 70c through a metal wiring board (not illustrated). For example, the metal wiring board is formed to be bent by press processing or the like using a metal material such as a copper material, a copper-alloy-based material, an aluminum-alloy-based material, or iron-alloy-based material. For example, the semiconductor element 71 and the metal wiring board are bonded via a bonding material such as solder. The metal wiring board may be referred to as a lead frame. Note that, instead of the metal wiring board, a connecting member such as a conductive wire may be disposed. In addition, the semiconductor element 71 is directly or indirectly connected to the control terminal 60 by using a connection member. For example, ten control terminals 60 are arranged for each circuit substrate 70 in the housing wall 11 of the case 10. More specifically, in each circuit substrate 70, the ten control terminals 60 are arranged so that the M terminal 50 is interposed in the left-right direction (X direction) five by five.

Note that, in the above description, an example is described in which three main terminals (the P terminal 30, the N terminal 40, and the M terminal 50) are provided on each of the three circuit substrates 70. However, the semiconductor device 1 only needs to include at least one circuit substrate 70, and the number of main terminals and control terminals can be set arbitrarily.

The metal base 80 is a rectangular plate-shaped member. The metal base 80 is a member that functions as a heat conducting member that conducts heat generated by the semiconductor element 71 to a cooler (not illustrated) positioned below the metal base 80 and is formed, for example, of a metal plate such as a copper plate or an aluminum plate. The metal base 80 and the cooler are bonded via a thermal conductive material such as a thermal grease or a thermal compound.

Next, fitting of the lid 20 into the case 10 is described.

First, the semiconductor element 71 is mounted on the circuit substrate 70, and the gel G is injected into the substrate housing regions A1 to A3 in a state where the P terminal 30, the N terminal 40, the M terminal 50, and the control terminal 60 are electrically connected to the circuit substrate 70 or the semiconductor element 71.

Then, the lid 20 is horizontally placed in the housing wall 11 so as to cover the substrate housing regions A1 to A3. The bottom surface of the lid 20 comes into contact with the upper surface of each of the lid receivers 11c, 11d, and 11e, the first partition wall 12, and the second partition wall 13 illustrated in FIGS. 3 and 4, but each of the extending portions 21 to 24 is elastically deformed in the process of being placed. Specifically, the first extending portion 21 is deformed to the negative side in the X direction when the protrusion 21a is hooked on the first hook portion 11a. The second extending portion 22 is deformed to the positive side in the X direction when the protrusion 22a is hooked on the second hook portion 11b. The third extending portion 23 is deformed to the positive side in the X direction when the protrusion 23a is hooked on the third hook portion 12a. The fourth extending portion 24 is deformed to the negative side in the X direction when the protrusion 24a is hooked on the fourth hook portion 13a. Note that, when protrusions (not illustrated) extending upward are provided on the protrusions 21a to 24a, and the protrusions are fitted into recesses (not illustrated) or protrusions (not illustrated) provided on the bottom surfaces of the hook portions 11a, 11b, 12a, and 13a, the lid 20 can be more reliably fitted into the case 10.

As described above, the reaction force due to the deformation of the extending portions 21 to 24 is alleviated by each of the deformation holes 25a to 25f. In a state where the bottom surface of the lid 20 is in contact with the upper surfaces of the lid receivers 11c, 11d, and 11e, the first partition wall 12, and the second partition wall 13, the protrusions 21a to 24a of the respective extending portions 21 to 24 are hooked on the hook portions 11a, 11b, 12a, and 13a, and the respective extending portions 21 to 24 are elastically deformed so as to return to their original shapes.

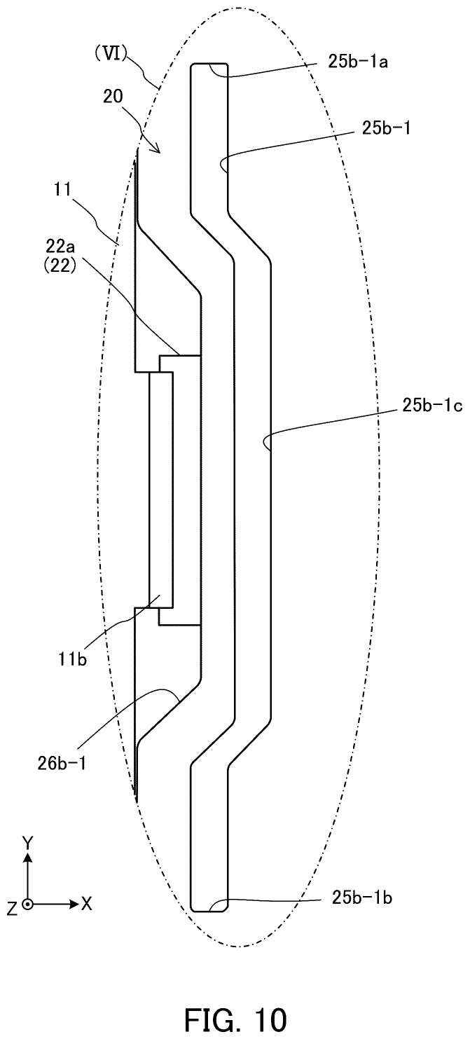

FIG. 10 is a plan view (corresponding to FIG. 6 which is an enlarged view of the VI portion in FIG. 1) illustrating a second deformation hole 25b-1 and the like in a first modification of the embodiment.

The second deformation hole 25b illustrated in FIG. 6 described above is a long hole extending in a straight line shape in the Y direction, but the second deformation hole 25b-1 in the first modification illustrated in FIG. 10 extends in the Y direction but is positioned at a central part 25b-1c with respect to both end parts (end portions 25b-1a and 25b-1b) away from the protrusion 22a of the second extending portion 22 in the longitudinal direction (the positive side in the X direction) of the lid 20. In the second deformation hole 25b-1, a central part 25b-1c extending in a straight line shape in the Y direction and both end parts (end portions 25b-1a and 25b-1b) extending in a straight line shape in the Y direction at positions on the negative side in the X direction with respect to the central part 25b-1c are integrally provided via parts extending obliquely. That is, the second deformation hole 25b-1 has a shape along the outer peripheral edge of the lid 20.

As described above, the central part 25b-1c is positioned on the positive side in the X direction with respect to both end parts (end portions 25b-la and 25b-1b), and the second deformation hole 25b-1 has a shape along the outer peripheral edge of the lid 20, so that the length in the longitudinal direction from the other end (left end) of the lid 20 to the end portion 25b-la, the length in the longitudinal direction from the recess portion 26b-1 to the central part 25b-1c, and the length in the longitudinal direction from the other end (left end) of the lid 20 to the end portion 25b-1b can be made constant. Therefore, the deformation of the second extending portion 22 is promoted, and the reaction force due to the deformation of the second extending portion 22 can be easily alleviated more reliably. In the first modification, unlike recess portion 26b illustrated in FIG. 6, the recess portion 26b-1 does not have a rectangular shape in plan view, and the width thereof in the Y direction is continuously narrowed from an opening part (left end) toward the positive side (right side) in the X direction.

Here, the first deformation hole 25a can also have a bilaterally symmetrical shape with the second deformation hole 25b-1. In addition, the third deformation hole 25d may have the same shape as the second deformation hole 25b-1, or the fourth deformation hole 25f may have a bilaterally symmetrical shape with respect to the second deformation hole 25b-1. In addition, the recess portion 26a may have a shape that is bilaterally symmetrical with the recess portion 26b-1.

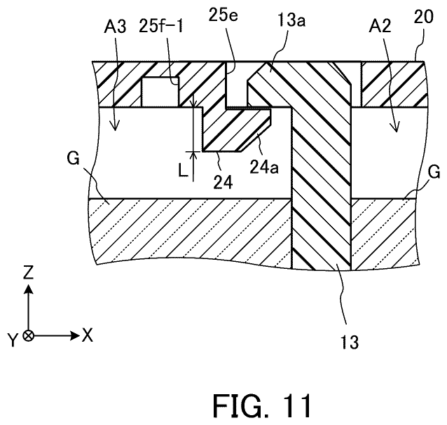

FIG. 11 is a cross-sectional view (corresponding to FIG. 9 that is the cross-sectional view taken along line IX-IX of FIG. 8) illustrating a fourth deformation hole 25f-1 and the like in a second modification of the embodiment.

Each of the deformation holes 25a to 25f penetrates the lid 20 in the thickness direction (Z direction) in the example described above but may be a recess provided in the bottom surface of the lid 20 (the surface on the substrate housing regions A1 to A3 side) in the direction from the bottom surface to the upper surface of the lid 20 (the positive side in the Y direction) as in the fourth deformation hole 25f-1 illustrated in FIG. 11. In particular, when the thickness of the lid 20 is large, the depth of the deformation hole such as the fourth deformation hole 25f-1 that does not penetrate the lid 20 is increased, and the reaction force due to the deformation of the extending portions 21 to 24 is easily alleviated.

In the present embodiment described above, the semiconductor device 1 includes the case 10 that houses the circuit substrate 70 on which the semiconductor element 71 is mounted in the substrate housing regions A1 to A3, and the lid 20 that covers the substrate housing regions A1 to A3. The lid 20 includes the plurality of extending portions 21 to 24 provided with the protrusions 21a to 24a extending toward the substrate housing regions A1 to A3 side (the negative side in the Z direction), and the plurality of deformation holes 25a to 25f, for example, that alleviate reaction force due to deformation of the plurality of extending portions 21 to 24. The case 10 includes the plurality of hook portions 11a, 11b, 12a, and 13a on which the protrusions 21a to 24a of the extending portions 21 to 24 are respectively hooked. The plurality of extending portions 21 to 24 include the first extending portion 21 including the protrusion 21a protruding in a first direction (the positive side in the X direction) and the second extending portion 22 including the protrusion 22a protruding in a second direction (the negative side in the X direction) opposite to the first direction (the positive side in the X direction).

As a result, the protrusions 21a and 22a of the first extending portion 21 and the second extending portion 22 protruding in directions opposite to each other can be hooked on the first hook portion 11a and the second hook portion 11b of the case 10. Therefore, the lid 20 can be reliably fitted into the case 10. Since the plurality of deformation holes 25a to 25f alleviate the reaction force due to the deformation of the plurality of extending portions 21 to 24, it is not required for the plurality of extending portions 21 to 24 to secure the length L for alleviating the warping force, and the length L of the extending portions 21 to 24 extending toward the substrate housing regions A1 to A3 (the negative side in the Z direction) can be shortened. As a result, the height of the extending portions 21 to 24 and, in turn, the height of the semiconductor device 1 can be reduced. Therefore, according to the present embodiment, the lid 20 can be reliably fitted into the case 10, and the height reduction of the semiconductor device 1 can be achieved. Further, since the reaction force due to the deformation of the extending portions 21 to 24 can be alleviated, it is also possible to prevent the extending portions 21 to 24 from being broken when the lid 20 is fitted. In addition, as compared with an aspect in which an adhesive material is used for fixing the case 10 and the lid 20, cost reduction and the like can be achieved by omitting or reducing an adhesive material. In addition, even when the circuit substrate 70 and the like are sealed with the gel G, the length L (height) of the extending portions 21 to 24 can be shortened, and thus the heights of the substrate housing regions A1 to A3 can be reduced.

In addition, in the present embodiment, the first extending portion 21 and the second extending portion 22 are positioned on both end sides in the longitudinal direction (X direction) of the lid 20, and the protrusion 21a of the first extending portion 21 and the protrusion 22a of the second extending portion 22 protrude away from each other in the longitudinal direction of the lid 20.

As a result, the protrusions 21a and 22a of the first extending portion 21 and the second extending portion 22 are hooked on the first hook portion 11a and the second hook portion 11b from the inside of the housing wall 11 (case 10) (so-called inner hook). As described above, since the first extending portion 21 and the second extending portion 22 are positioned inside the housing wall 11, miniaturization in size of the semiconductor device 1 in plan view can be achieved as compared with an aspect in which the protrusion is hooked on the case 10 from the outside of the housing wall 11 (so-called outer hook). In addition, by adopting the inner hook, it is possible to more reliably prevent the hook from being released due to warpage of the lid 20 caused by a temperature change or the like, compared with the outer hook. However, the above-described outer hook configuration in which the first extending portion 21 and the second extending portion 22 are hooked on the case 10 from the outside of the housing wall 11 may be adopted. In this case, the protrusions 21a and 22a of the first extending portion 21 and the second extending portion 22 are provided so as to protrude in directions approaching each other. As the plurality of extending portions 21 to 24, a configuration including only the first extending portion 21 and the second extending portion 22 may be adopted, or the first extending portion 21 and the second extending portion 22 may be provided at positions different from both ends of the lid 20 in the longitudinal direction (X direction).

In the present embodiment, the plurality of extending portions 21 to 24 further include one or more intermediate extending portions (the third extending portion 23 and the fourth extending portion 24) positioned between the first extending portion 21 and the second extending portion 22 positioned on both end sides of the lid 20 in the longitudinal direction (X direction).

Therefore, the lid 20 can be hooked on the case 10 not only on both end sides of the lid 20 in the longitudinal direction but also in an intermediate part. As a result, the lid 20 is less likely to be released from the case 10 even in a situation where warpage of the lid 20 due to a temperature change or the like occurs, or vibration is applied to the semiconductor device 1. Therefore, the lid 20 can be more reliably fitted into the case 10.

In the present embodiment, one or more intermediate extending portions positioned between the first extending portion 21 and the second extending portion 22 of the lid 20 in the longitudinal direction (X direction) include the third extending portion 23 including the protrusion 23a protruding in the second direction (the negative side in the X direction) and the fourth extending portion 24 including the protrusion 24a protruding in the first direction (the positive side in the X direction).

As a result, the lid 20 can be hooked on the case 10 in directions in which the protrusion 21a of the first extending portion 21 protruding in the first direction (the positive side in the X direction) and the protrusion 23a of the third extending portion 23 protruding in the second direction (the negative side in the X direction) are away from each other. Further, the lid 20 can be hooked on the case 10 in directions in which the protrusion 22a of the second extending portion 22 protruding in the second direction (the negative side in the X direction) and the protrusion 24a of the fourth extending portion 24 protruding in the first direction (the positive side in the X direction) are away from each other. Therefore, the lid 20 can be further more reliably fitted into the case 10.

In the present embodiment, the case 10 includes the plurality of substrate housing regions A1 to A3, and the first partition wall 12 and the second partition wall 13 (an example of one or more partition walls) that partition the plurality of substrate housing regions A1 to A3. The plurality of hook portions 11a, 11b, 12a, and 13a include the third hook portion 12a and the fourth hook portion 13a (an example of one or more intermediate hook portions) which are provided on the first partition wall 12 and the second partition wall 13 and on which the protrusions 23a and 24a of the intermediate extending portions (the third extending portion 23 and the fourth extending portion 24) are hooked.

As a result, the protrusions 23a and 24a of the third extending portion 23 and the fourth extending portion 24 can be hooked on the case 10 (the third hook portion 12a of the first partition wall 12 and the fourth hook portion 13a of the second partition wall 13) with a simple configuration using the first partition wall 12 and the second partition wall 13. Therefore, it is possible to further achieve the height reduction of the semiconductor device 1 and the miniaturization of the semiconductor device 1.

In the present embodiment, the plurality of deformation holes 25a to 25e include, for example, the third deformation holes 25c and 25d and the fourth deformation holes 25e and 25f (examples of intermediate deformation holes) that alleviate reaction force due to deformation of the third extending portion 23 and the fourth extending portion 24 on both sides of the third extending portion 23 and the fourth extending portion 24 (examples of intermediate extending portions) in the longitudinal direction (X direction) of the lid 20.

Therefore, by narrowing the widths of the third extending portion 23 and the fourth extending portion 24 in the longitudinal direction (X direction) of the lid 20 between the third deformation holes 25c and 25d and between the fourth deformation holes 25e and 25f, the third extending portion 23 and the fourth extending portion 24 can be easily bent. As a result, the length L of the third extending portion 23 and the fourth extending portion 24 in the Z direction can be further shortened, and thus it is possible to further achieve the height reduction of the semiconductor device 1.

In the present embodiment, in the direction (Y direction) orthogonal to the longitudinal direction (X direction) of the lid 20 and the depth direction (Z direction) of the substrate housing regions A1 to A3, the first deformation hole 25a provided on the first extending portion 21 side extends longer (for example, in a straight line shape) than the first extending portion 21, and the second deformation hole 25b provided on the second extending portion 22 side extends longer (for example, in a straight line shape) than the second extending portion 22.

As a result, by narrowing the width of the first extending portion 21 and the front and rear portions thereof in the longitudinal direction (X direction) of the lid 20 by using the right end (the end portion on the positive side in the X direction) of the lid 20 and the first deformation hole 25a, the first extending portion 21 can be easily bent. Similarly, by narrowing the width of the second extending portion 22 and the front and rear portions thereof in the longitudinal direction (X direction) of the lid 20 by using the left end (the end portion on the negative side in the X direction) of the lid 20 and the second deformation hole 25b, the second extending portion 22 can be easily bent. As a result, the length L of the first extending portion 21 and the second extending portion 22 in the Z direction can be further shortened, and thus it is possible to further achieve the height reduction of the semiconductor device 1.

In addition, in the present embodiment, the first extending portion 21 and the second extending portion 22 positioned on both end sides in the longitudinal direction (X direction) of the lid 20 are provided at positions (the recess portions 26a and 26b) recessed in the longitudinal direction from both ends in the longitudinal direction (X direction) of the lid 20. In the first modification of the present embodiment, the second deformation hole 25b-1 that alleviates reaction force due to deformation of the second extending portion 22 (the same applies to the first deformation hole 25a that alleviates reaction force due to deformation of the first extending portion 21) is formed along the outer peripheral edge of the lid 20. For example, the second deformation hole 25b-1 extends in a direction (Y direction) orthogonal to the longitudinal direction (X direction) of the lid 20 and the depth direction (Z direction) of the substrate housing regions A1 to A3 and is positioned in the central part 25b-1c from both end parts (the end portions 25b-1a and 25b-1b) so that the deformation hole 25b-1 is away from the protrusion 22a of the second extending portion 22 that alleviates the reaction force caused by the deformation in the longitudinal direction (X direction) of the lid 20.

Therefore, since the length in the longitudinal direction from the other end (left end) of the lid 20 to the end portion 25b-la, the length in the longitudinal direction from the recess portion 26b-1 to the central part 25b-1c, and the length in the longitudinal direction from the other end (left end) of the lid 20 to the end portion 25b-1b can be made constant, the second extending portion 22 can be easily bent. As a result, the length L of the second extending portion 22 (or the first extending portion 21) in the Z direction can be further shortened, and thus it is possible to further achieve the height reduction of the semiconductor device 1.

In the present embodiment, the first deformation hole 25a and the second deformation hole 25b are provided adjacent to the first extending portion 21 and the second extending portion 22.

Therefore, as compared with an aspect in which the first deformation hole 25a and the second deformation hole 25b are not adjacent to the first extending portion 21 and the second extending portion 22, the first extending portion 21 and the second extending portion 22 can be easily bent, and the reaction force due to deformation can be more reliably alleviated.

In the present embodiment, the deformation holes 25a to 25f penetrate the lid 20.

Therefore, as compared with an aspect in which a deformation hole not penetrating the lid 20 is used, the extending portions 21 to 24 can be easily bent. As a result, the length L of the extending portions 21 to 24 in the Z direction can be further shortened, and thus it is possible to further achieve the height reduction of the semiconductor device 1.

In the second modification of the present embodiment, the fourth deformation hole 25f-1 is a recess provided in the surface (bottom surface) of the lid 20 on the substrate housing regions A1 to A3 side.

As a result, unlike the deformation holes 25a to 25f penetrating the lid 20, it is possible to prevent dust or the like from entering the substrate housing regions A1 to A3 from the deformation holes not penetrating the lid 20 such as the fourth deformation hole 25f-1.

Hereinafter, the invention described in the claims of the originally filed application is additionally described.

### Supplementary Note 1

A semiconductor device including:
a case that houses a circuit substrate on which a semiconductor element is mounted in a substrate housing region; and
a lid that covers the substrate housing region,
in which the lid includes a plurality of extending portions including a first extending portion extending toward the substrate housing region side and including a protrusion protruding in a first direction and a second extending portion extending toward the substrate housing region side and including a protrusion protruding in a second direction opposite to the first direction, and a plurality of deformation holes, and
the case includes a plurality of hook portions on which the protrusions of the extending portions are respectively hooked.

### Supplementary Note 2

The semiconductor device according to Supplementary Note 1,
in which the first extending portion and the second extending portion are positioned on both end sides in a longitudinal direction of the lid, and
the protrusion of the first extending portion and the protrusion of the second extending portion protrude away from each other in the longitudinal direction of the lid.

### Supplementary Note 3

The semiconductor device according to Supplementary Note 2,
in which the plurality of extending portions further include one or more intermediate extending portions of which positions in the longitudinal direction of the lid are positioned between the first extending portion and the second extending portion.

### Supplementary Note 4

The semiconductor device according to Supplementary Note 3,
in which the one or more intermediate extending portions include a third extending portion including the protrusion protruding in the second direction and a fourth extending portion including the protrusion protruding in the first direction.

### Supplementary Note 5

The semiconductor device according to Supplementary Note 3,
in which the case includes a plurality of the substrate housing regions and one or more partition walls that partition the plurality of substrate housing regions, and
the plurality of hook portions include one or more intermediate hook portions provided on the partition wall and on which the protrusions of the intermediate extending portion are hooked.

### Supplementary Note 6

The semiconductor device according to Supplementary Note 3,
in which the plurality of deformation holes include intermediate deformation holes provided on both sides of the intermediate extending portion in the longitudinal direction of the lid.

### Supplementary Note 7

The semiconductor device according to Supplementary Note 2,
in which in a direction orthogonal to the longitudinal direction of the lid and a depth direction of the substrate housing region, the deformation hole provided on the first extending portion side extends longer than the first extending portion, and the deformation hole provided on the second extending portion side extends longer than the second extending portion.

### Supplementary Note 8

The semiconductor device according to Supplementary Note 2,
wherein the first extending portion and the second extending portion are provided at positions recessed in the longitudinal direction from the both ends in the longitudinal direction of the lid, and
the deformation hole is formed along an outer peripheral edge of the lid.

### Supplementary Note 9

The semiconductor device according to Supplementary Note 1,
in which the plurality of deformation holes are provided adjacent to the first extending portion and the second extending portion.

### Supplementary Note 10

The semiconductor device according to Supplementary Note 1,
in which the deformation hole penetrates the lid.

### Supplementary Note 11

The semiconductor device according to Supplementary Note 1,
in which the deformation hole is a recess provided in a surface of the lid on the substrate housing region side.

As described above, the present invention exhibits an effect of achieving the height reduction of a semiconductor device in which a lid is fitted into a case, and is useful for, for example, a power semiconductor device.

What is claimed is:

1. A semiconductor device, comprising:
a circuit substrate having a semiconductor element thereon;
a case surrounding a periphery of the circuit substrate so as to house the circuit substrate therein; and
a lid disposed above the circuit substrate so as to close the case at an upper side thereof, wherein
the lid includes a plurality of extending portions including a first extending portion and a second extending portion, and a plurality of deformation holes respectively provided for respective ones of the first extending portion and the second extending portion, the plurality of extending portions each extending, from a lower surface of the lid that faces the circuit substrate, toward the circuit substrate, and each having a protrusion at an end thereof, the protrusion of the first extending portion protruding in a first direction and the protrusion of the second extending portion protruding in a second direction opposite to the first direction, and
the case includes a plurality of hooked portions that respectively hook onto respective ones of the protrusions of the plurality of extending portions.

2. The semiconductor device according to claim 1, wherein
the first extending portion and the second extending portion are respectively positioned at facing sides of the case in a direction orthogonal to the first and second directions, and
the first and second directions are a longitudinal direction of the lid so that the protrusion of the first extending portion and the protrusion of the second extending portion respectively protrude away from each other in the longitudinal direction of the lid.

3. The semiconductor device according to claim 2, wherein the plurality of extending portions further includes one or more intermediate extending portions between the first extending portion and the second extending portion, the plurality of extending portions and the one or more intermediate extending portions being aligned in the longitudinal direction of the lid.

4. The semiconductor device according to claim 3, wherein the one or more intermediate extending portions include a third extending portion and a fourth extending portion, the protrusion of the third extending portion protruding in the second direction and the protrusion of the fourth extending portion protruding in the first direction.

5. The semiconductor device according to claim 3, wherein
the case includes one or more partition walls that respectively partition a space inside the case into a plurality of subspaces, and
the plurality of hooked portions includes one or more intermediate hooked portions respectively provided at respective ones of the one or more partition walls, the one or more intermediate hooked portions respectively hooking onto corresponding ones of protrusions of the one or more intermediate extending portions.

6. The semiconductor device according to claim 3, wherein the plurality of deformation holes includes intermediate deformation holes, two of which are respectively provided for a corresponding one of the one or more intermediate extending portions, and sandwich therebetween the corresponding one of the one or more intermediate extending portions from the longitudinal direction of the lid.

7. The semiconductor device according to claim 2, wherein in a direction orthogonal to the longitudinal direction of the lid and parallel to the surface of the circuit substrate, the deformation hole for the first extending portion has a length longer than a length of the first extending portion, and the deformation hole for the second extending portion has a length longer than a length of the second extending portion.

8. The semiconductor device according to claim 2, wherein
the lid has a first recess and a second recess that are respectively provided in opposite longitudinal directions so that bottoms of the first recess and second recess approach each other,
the first extending portion and the second extending portion are respectively provided at the first recess and the second recess, and
the deformation holes of the first extending portion and second extending portion are respectively formed along an outer peripheral edge of the lid.

9. The semiconductor device according to claim 1, wherein the plurality of deformation holes are respectively provided adjacent to one of the first extending portion and the second extending portion.

10. The semiconductor device according to claim 1, wherein the plurality of deformation holes respectively penetrate through the lid.

11. The semiconductor device according to claim 1, wherein each of the plurality of deformation holes is a recess provided in the bottom surface of the lid.
